(19) United States
(12) Patent Application Publication
(10) Pub. No.: US 2002/0119682 A1
(43) Pub. Date: Aug. 29, 2002

(54) Printed circuit board configuration

(76) Inventor: Michael Schmid, Dillingen (DE)

Correspondence Address: LERNER AND GREENBERG, P.A., POST OFFICE BOX 2480, HOLLYWOOD, FL, 33022-2480, US

(21) Appl. No.: 10/084,102

(22) Filed: Feb. 27, 2002

(30) Foreign Application Priority Data
Feb. 28, 2001 (DE) 101 09 571.6

(51) Int. Cl. H05K 1/00

(52) U.S. Cl. 439/65

(57) ABSTRACT

A printed circuit board configuration includes a first printed circuit board having defined dimensions and a second printed circuit board, which can be connected to the first printed circuit board by a plug connector. The printed circuit board configuration according to the invention is characterized in that, in the connected state, the first and second printed circuit boards are situated in a plane and the dimensions of the second printed circuit board are dimensioned such that the configuration including the first and second printed circuit boards has second defined dimensions. Preferably, the defined dimensions corresponds to a first standard, in particular, the μATX dimension standard, and the second defined dimensions correspond to a second standard, in particular, the ATX dimension standard.

### BACKGROUND OF THE INVENTION

1. Field of the Invention

The invention relates to a printed circuit board configuration having a first printed circuit board with first defined dimensions and a second printed circuit board, which can be connected to the first printed circuit board by a plug connector.

Similar printed circuit board configurations are in the prior art as so-called riser cards. The riser cards are used for the purpose of providing additional slots. In such a case, a riser card is plugged perpendicularly into a so-called PCI slot. The printed circuit boards plugged onto the riser card, so-called expansion cards, then lie parallel to the first printed circuit board. As a result, they are situated in a region in which the spatial configuration can clash with other components disposed on the printed circuit board. Linking to the bus system of the main board is also problematic because PCI slots are actually not provided for linking and controlling a plurality of expansion cards.

As an alternative, relatively large printed circuit boards having more slots for expansion cards are provided as the main board from the outset. To be able to offer systems with a small number of slots and small dimensions as well as systems with a large number of slots and comparatively large dimensions, then, two different types of main board are developed, manufactured and stored, which causes additional costs.

### SUMMARY OF THE INVENTION

It is accordingly an object of the invention to provide a printed circuit board configuration that overcomes the hereinafore-mentioned disadvantages of the heretofore-known devices of this general type and that enables simple expansion of the first printed circuit board by further components, in particular, slots.

With the foregoing and other objects in view, there is provided, in accordance with the invention, a printed circuit board configuration includes a first printed circuit board having first defined dimensions and a first portion of a plug connector, the first printed circuit board extending in a given plane, and a second printed circuit board having a second portion of the plug connector, the second printed circuit board connectable to the first printed circuit board through the plug connector to form a connected configuration.

The first and second printed circuit boards both extend in the given plane when connected in the connected configuration. The second printed circuit board has dimensions such that the connected configuration has second defined dimensions.

The invention provides a printed circuit board configuration that overcomes the hereinafore-mentioned disadvantages and enables simple expansion of the first printed circuit board by further components, in particular, slots, by a configuration that, in the connected state, situates the first and second printed circuit boards in a plane and the dimensions of the second printed circuit board are dimensioned such that the configuration including the first and second printed circuit boards has second defined dimensions.

According to the invention, then, a second printed circuit board is connected to the first printed circuit board through a plug connector, both the size of the first printed circuit board and the size of the configuration including the first and second printed circuit boards corresponding to defined dimensions. This is the case, for example, with main boards for data processing systems, where different standards have been established. One of the standards relates to so-called ATX boards and the corresponding other standard in respect thereof is referred to as μATX. The size of ATX boards is 244 mm×305 mm while the size of μATX boards is 244 mm×244 mm.

Accordingly, there are housings suitable for ATX boards and other housings suitable for μATX boards. Stock keeping is complicated because both printed circuit boards have to be stocked. Moreover, the development of two different boards is very costly, even though they have identical or largely identical functionalities.

The configuration according to the invention proves to be particularly advantageous if all the important components are situated on the first printed circuit board and the second printed circuit board only has plug devices for receiving plug-in cards. In such a case, the costly development steps concern only the first printed circuit board, so that the outlay only has to be expended once for different sizes of printed circuit boards including the first and second printed circuit boards or only the first printed circuit board. On the second printed circuit board, all that is required are the plug-in cards or an interconnection of the connections for leading on to the plug-in connection, this being comparatively simple from a construction standpoint.

With the objects of the invention in view, there is also provided a printed circuit board assembly including a first printed circuit board having dimensions corresponding to a first dimension standard, the first printed circuit board substantially extending in a given plane, and a second printed circuit board removeably connected to the first printed circuit board. The first and second printed circuit boards form a connected configuration when the second printed circuit board is connected to the first printed circuit board, and both extend in the given plane when connected in the connected configuration. The second printed circuit board is dimensioned to have the connected configuration correspond to a second dimension standard.

In accordance with a concomitant feature of the invention, the first printed circuit board is a main board of a data processing device and the second printed circuit board has slots for receiving plug-in cards.

Other features that are considered as characteristic for the invention are set forth in the appended claims.

Although the invention is illustrated and described herein as embodied in a printed circuit board configuration, it is, nevertheless, not intended to be limited to the details shown because various modifications and structural changes may be made therein without departing from the spirit of the invention and within the scope and range of equivalents of the claims.

The construction and method of operation of the invention, however, together with additional objects and advantages thereof, will be best understood from the following description of specific embodiments when read in connection with the accompanying drawings.

### BRIEF DESCRIPTION OF THE DRAWINGS

FIG. 1 is a plan view of a first exemplary embodiment of a printed circuit board configuration according to the invention;

FIG. 2 is a plan view of a more detailed version of the embodiment of FIG. 1,

FIG. 3 is a fragmentary, plan view of a detail of a PCI slot of FIG. 2; and

FIG. 4 is a fragmentary, cross-sectional view of the PCI slot of FIG. 3.

### DESCRIPTION OF THE PREFERRED EMBODIMENTS

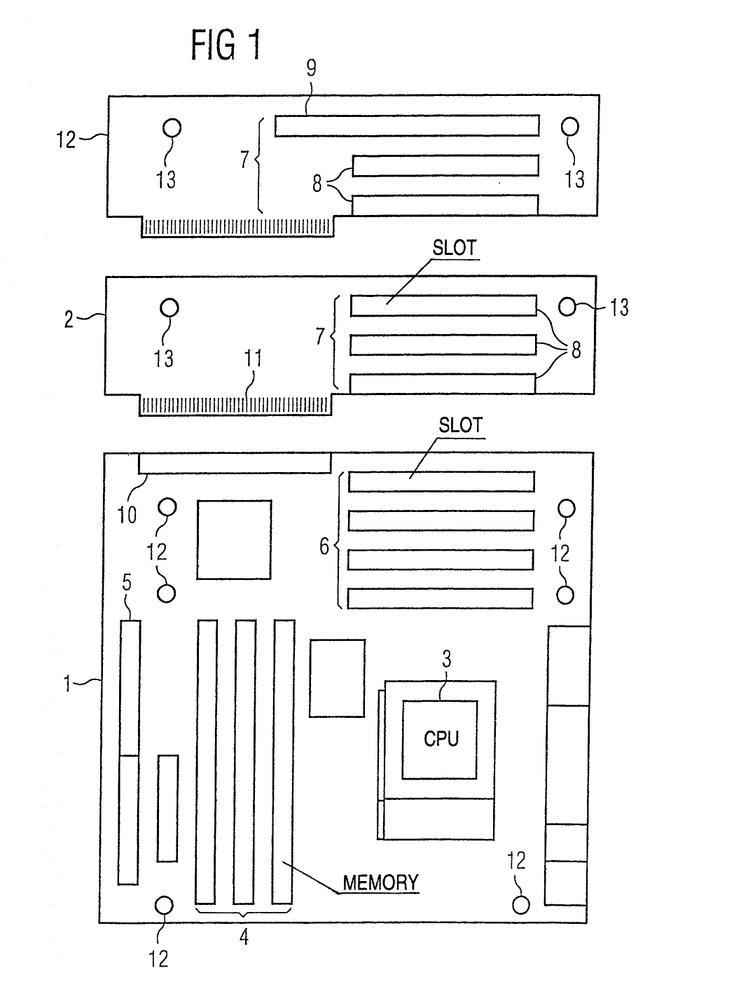

Referring now to the figures of the drawings in detail and first, particularly to FIG. 1 thereof, there is shown a configuration with two printed circuit boards 1 and 2 in a simplified illustration. As an alternative to the second printed circuit board 2, it is also possible to provide a printed circuit board 12. The first printed circuit board 1 is the main board of a data processing device and has a CPU 3, memory components 4, connections 5, and slots 6 for expansion cards. The length and width of the printed circuit board 1 is defined. It is determined by standardization or quasi-standards with which, inter alia, the housing size, etc., are coordinated. Also coordinated is, for example, the placement of the holes 12 for fastening screws. In such a case, the printed circuit board 1 is a main board according to the μATX standard which has a size of 244 mm×244 mm.

In many cases, however, there is a demand for additional slots 7 for expansion cards, which also necessitate a larger housing. In such a case, use has been made hitherto of another main board which has the required additional slots. The size of such an ATX board is 244 mm×305 mm. The provision of these different main boards causes considerable costs in development, production and storage. With the use of a configuration according to the invention, only the first printed circuit board 1 is developed according to the μATX standard and, in the cases in which further slots 7 are necessary, the second printed circuit board 2 is connected, as an expansion printed circuit board with respect to the first printed circuit board 1, to the printed circuit board 1 by a plug connection 10 and 11. To eliminate the use of a special housing for such an expanded printed circuit board configuration, the invention provides for the dimensions of the second printed circuit boards to be configured such that the configuration including the first and second printed circuit boards 1 and 2 has second defined dimensions, namely in accordance with the ATX standard. Holes 13 for fastening screws are ideally provided on the second printed circuit board 2 such that they likewise correspond to the position for holes according to the ATX standard. Consequently, it is possible to use a standard housing for ATX boards and all the corresponding standard components.

The printed circuit board 2 in FIG. 1 is equipped with three PCI slots 8. Naturally, conductor tracks are provided between a plug connector 11 for connection to the first printed circuit board 1 and the PCI slots 8, in accordance with the prescribed connection of the slots 8. The conductor connections are not illustrated to preserve clarity of FIG. 1.

As an alternative to the second printed circuit board 2, it is possible to use a second printed circuit board 12 that, in the case shown, has two PCI slots 8 and one ISA slot 9. Such a second printed circuit board 12 can beneficially be used if the user of the printed circuit board configuration requires an ISA slot 9, even though such a slot is no longer provided in the case of modern main boards. An ISA slot 9 is required if older plug-in cards are to be used in a new data processing device but the manufacturer cannot provide a PCI version of the plug-in card.

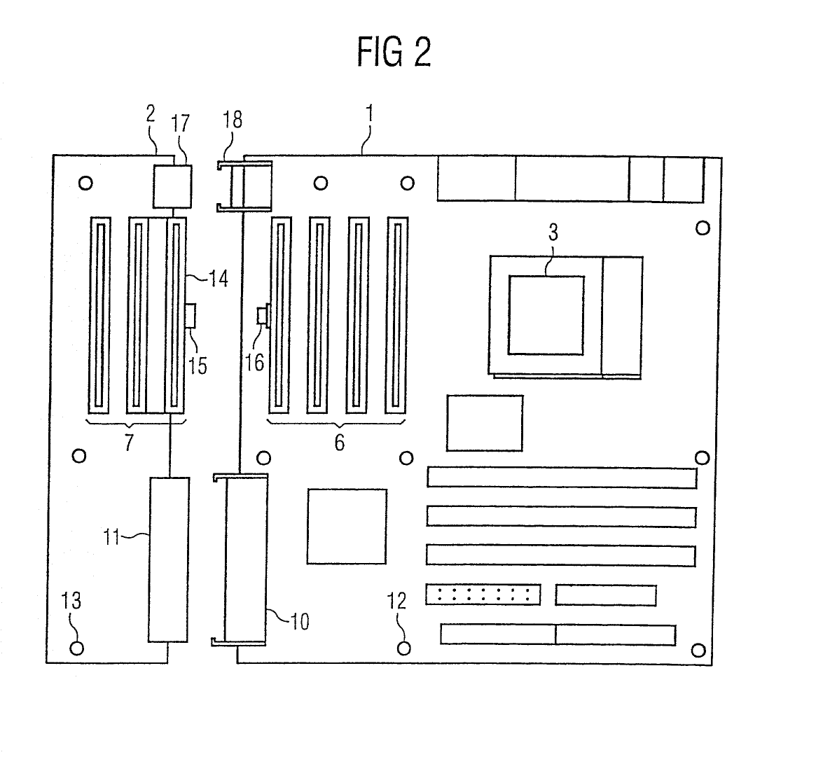

The printed circuit board configuration including the first printed circuit board 1 and the second printed circuit board 2 is illustrated in greater detail in the illustration of FIG. 2. The plug connector 10 on the first printed circuit board 1 for the connection of the second printed circuit board 2 is to be provided only when an expansion of the first printed circuit board 1 with the second printed circuit board 2 in accordance with the invention is actually provided. Otherwise, in the course of a uniform printed circuit board construction, only the connections for the plug connector 10 are provided. Mounting is not affected, however, so that costs can be saved at this point. The plug connectors 10 and 11 are embodied mechanically solidly such that a reliable electrical connection can be ensured even in the event of mechanical loading through the insertion of expansion cards into slots of the second printed circuit board 2.

The mechanical stability of the second printed circuit board 2 constitutes a certain problem because the mechanically acting forces through the insertion of expansion cards into the slots 7 of the second printed circuit board can be absorbed only by two supporting points at the fastening screws in the holes 13.

Therefore, in an advantageous manner, the voltage supply of the second printed circuit board 2 is likewise embodied mechanically solidly by plug connectors 17 and 18 and, moreover, is disposed on the other side of the connection region between the first and second printed circuit boards 1 and 2.

Furthermore, for the slots 7, a configuration is proposed that makes it possible, despite the two printed circuit boards 1, 2 being attached to one another, to ensure a distance between the slots 6 and 7, respectively, as is the case with a special ATX board. Specifically, one of the PCI connector strips 14 extends beyond the edge of the second printed circuit board 2 in order, in the plugged-together state, to bear on the surface of the first printed circuit board 1. As a result, forces acting on the second printed circuit board 2 are mechanically transmitted to the first printed circuit board 1. Moreover, a holding lug 15 is provided, which, in conjunction with corresponding latching recesses 16, ensures, by latching in, that the two printed circuit boards 1, 2 can be properly connected to one another and cannot be separated again by slipping, for example.

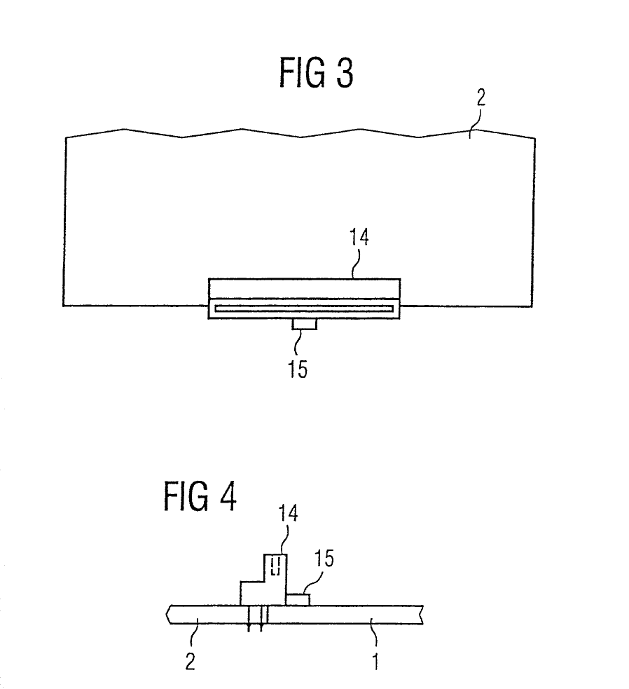

The special PCI connector strip is shown enlarged in FIG. 3. FIG. 4 shows the special PCI connector strip 14 in a cross-section, where it can be seen that the connector strip 14 is electrically connected to the printed circuit board 2, but mechanically there is also a connection to the first printed circuit board 1.

Despite the printed circuit board configuration according to the invention, two different components still have to be provided for the logistics. However, because the second printed circuit boards 2 do not contain sensitive electronic components and, moreover, are significantly smaller than the first printed circuit boards 1, a cost advantage also results for the logistics.

I claim:

1. A printed circuit board configuration, comprising:
a first printed circuit board having first defined dimensions and a first portion of a plug connector, said first printed circuit board extending in a given plane;
a second printed circuit board having a second portion of said plug connector, said second printed circuit board connectable to said first printed circuit board through said plug connector to form a connected configuration;
said first and second printed circuit boards both extending in said given plane when connected in said connected configuration; and
said second printed circuit board having dimensions such that said connected configuration has second defined dimensions.

2. The configuration according to claim 1, wherein:
said first defined dimensions correspond to a first standard; and
said second defined dimensions correspond to a second standard.

3. The configuration according to claim 2, wherein said first standard is the μATX dimension standard.

4. The configuration according to claim 2, wherein said second standard is the ATX dimension standard.

5. The configuration according to claim 2, wherein:
said first standard is the μATX dimension standard; and
said second standard is the ATX dimension standard.

6. The configuration according to claim 1, wherein:
said first printed circuit board is a main board of a data processing device; and
said second printed circuit board has slots for receiving plug-in cards.

7. The configuration according to claim 5, wherein:
said first printed circuit board is a main board of a data processing device; and
said second printed circuit board has slots for receiving plug-in cards.

8. A printed circuit board assembly, comprising:
a first printed circuit board having dimensions corresponding to a first dimension standard, said first printed circuit board substantially extending in a given plane;
a second printed circuit board removeably connected to said first printed circuit board;
said first and second printed circuit boards:
forming a connected configuration when said second printed circuit board is connected to said first printed circuit board; and
both extending in said given plane when connected in said connected configuration; and
said second printed circuit board being dimensioned to have said connected configuration correspond to a second dimension standard.

9. The configuration according to claim 8, wherein said first dimension standard is the μATX dimension standard.

10. The configuration according to claim 8, wherein said second dimension standard is the ATX dimension standard.

11. The configuration according to claim 8, wherein:
said first dimension standard is the μATX dimension standard; and
said second dimension standard is the ATX dimension standard.

12. The configuration according to claim 8, wherein:
said first printed circuit board is a main board of a data processing device; and
said second printed circuit board has slots for receiving plug-in cards.

13. The configuration according to claim 11, wherein:
said first printed circuit board is a main board of a data processing device; and
said second printed circuit board has slots for receiving plug-in cards.
